(19) United States
(12) Patent Application Publication
(10) Pub. No.: US 2009/0017275 A1
(43) Pub. Date: Jan. 15, 2009

(54) Heat-releasing printed circuit board and manufacturing method thereof

(75) Inventors: Eung-Suek Lee, Ansan-si (KR); Je-Gwang Yoo, Yongin-si (KR); Chang-Sup Ryu, Yongin-si (KR); Jun-Oh Hwang, Nam-gu (KR); Jee-Soo Mok, Yongin-si (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/076,428

(22) Filed: Mar. 18, 2008

(30) Foreign Application Priority Data
Jul. 9, 2007 (KR) 10-2007-0068523

(51) Int. Cl. H05K 3/00; B32B 3/10

(52) U.S. Cl. 428/201; 427/97.4

(57) ABSTRACT

A heat-releasing PCB and a method of manufacturing the PCB are disclosed. The method of manufacturing the heat-releasing printed circuit board includes: preparing a copper clad laminate, which has at least one copper layer stacked on at least one insulation layer; forming a coating layer, made from a paste having carbon nanotubes as a major constituent, on a surface of the copper layer; and forming a circuit pattern by removing portions of the coating layer and portions of the copper layer.

### CROSS-REFERENCE TO RELATED APPLICATIONS

This application claims the benefit of Korean Patent Application No. 10-2007-0068523 filed with the Korean Intellectual Property Office on Jul. 9, 2007, the disclosure of which is incorporated herein by reference in its entirety.

### BACKGROUND

1. Technical Field

The present invention relates to a heat-releasing printed circuit board, which can effectively release heat within the printed circuit board, and to a method of manufacturing the heat-releasing printed circuit board.

2. Description of the Related Art

As electronic products are currently becoming slimmer and given more functionalities, the printed circuit board (PCB) is being mounted with a greater number of passive components and higher-density, multilayer packages, the trend of which will continue into the future.

The PCB serves basically to connect various parts onto a printed circuit substrate according to the circuit design of electrical wiring, and to support the parts. However, with the greater number of passive parts or packages mounted, there is more electrical consumption and greater amounts of heat generated in the parts. This becomes important criteria in evaluating the reliability of the product as well as in user preferences for the product.

As such, there is a need for a functional PCB capable of effectively releasing and emitting heat generated due to high levels of functionality.

In a functional board, a portion of a heat-releasing metal, which is inserted within the heat-releasing PCB, may be exposed to the air, or may spread the heat generated in portions of high mounting density to other portions, to lower the temperature of the overall PCB.

Examples of heat-releasing metal that can be used in a heat-releasing PCB include stainless steel, aluminum, copper, etc. Although aluminum is lower in thermal conductivity than is copper, it is widely used due to its advantage in terms of cost. However, unlike copper, it is reactive to both acid and base solutions, so that problems may occur when using existing processes and equipment. As a result, etching, pickling, and desmearing solutions and equipment exclusive to aluminum use may be required.

Also, in the heat-releasing PCB structure according to the related art, the portions where heat is generated and the heat-releasing metal plate may be attached using prepreg, electrically conductive adhesive, and/or insulating resin, etc. However, since the basic compositions of such materials used in the attaching method largely include polymer components, it can be difficult to effectively transfer heat to the heat-releasing metal plate. The thermal conductivity of epoxy, for example, ranges from 0.17 to 0.23 W/mK.

### SUMMARY

An aspect of the invention is to provide a heat-releasing printed circuit board and to a method of manufacturing the heat-releasing PCB, which allow a superb heat-releasing effect, without using aluminum as in the related art.

One aspect of the invention provides a method of manufacturing a heat-releasing printed circuit board, which includes: preparing a copper clad laminate, which has at least one copper layer stacked on at least one insulation layer; forming a coating layer, made from a paste having carbon nanotubes as a major constituent, on a surface of the copper layer; and forming a circuit pattern by removing portions of the coating layer and portions of the copper layer.

The method may further include an operation of drying the coating layer, between the operations of forming the coating layer and forming the circuit pattern.

Also, between the operations of drying the coating layer and forming the circuit pattern, the method can include: forming at least one through-hole by perforating the copper clad laminate and the coating layer, and forming a plating layer inside the through-hole, in which case the operation of forming the circuit pattern may include removing portions of the plating layer.

Another aspect of the invention provides a method of manufacturing a heat-releasing printed circuit board, which includes: forming a first coating layer, made from a paste having carbon nanotubes as a major constituent, on a first copper layer; forming at least one bump, which includes carbon nanotubes as a major constituent, on a surface of the first coating layer; stacking an insulation layer such that the bump penetrates the insulation layer, and stacking a second copper layer on the insulation layer; and forming a circuit pattern by removing portions of the first copper layer, portions of the first coating layer, and portions of the second copper layer.

In certain embodiments, the method may further include an operation of drying the first coating layer, between the operations of forming the first coating layer and forming the bump.

A second coating layer that includes carbon nanotubes as a major constituent can be formed on the second copper layer, while stacking the second copper layer on the insulation layer can include stacking the second copper layer such that the second coating layer faces the insulation layer, and forming the circuit pattern can include removing portions of the second coating layer.

Still another aspect of the invention provides a multi-layered heat-releasing printed circuit board having at least one insulation layer and at least one circuit pattern stacked alternately, where the heat-releasing printed circuit board includes: a copper pattern and a coating layer stacked on a surface of the copper pattern, with carbon nanotubes included in the coating layer as a major constituent.

At least one bump containing carbon nanotubes may penetrate the insulation layer to connect adjacent circuit patterns.

As such, certain aspects of the invention provide effective release of heat from within a PCB, by having the circuit patterns include coating layers in which carbon nanotubes form a major constituent.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a flowchart for a method of manufacturing a heat-releasing printed circuit board according to a first disclosed embodiment of the invention.

FIG. 2A, FIG. 2B, FIG. 2C, FIG. 2D, and FIG. 2E are sectional views representing a flow diagram for manufacturing a heat-releasing printed circuit board according to a first disclosed embodiment of the invention.

FIG. 3 is a flowchart for a method of manufacturing a heat-releasing printed circuit board according to a second disclosed embodiment of the invention.

FIG. 4A, FIG. 4B, FIG. 4C, FIG. 4D, and FIG. 4E are cross-sectional views representing a flow diagram for manufacturing a heat-releasing printed circuit board according to a second disclosed embodiment of the invention.

FIG. 5 is a cross-sectional view of a multi-layered heat-releasing printed circuit board according to a third disclosed embodiment of the invention.

### DETAILED DESCRIPTION

The heat-releasing PCB and method of manufacturing the PCB according to certain embodiments of the invention will be described below in more detail with reference to the accompanying drawings. Those elements that are the same or are in correspondence are rendered the same reference numeral regardless of the figure number, and redundant explanations are omitted.

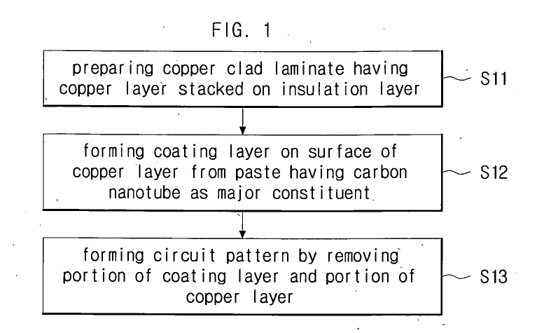

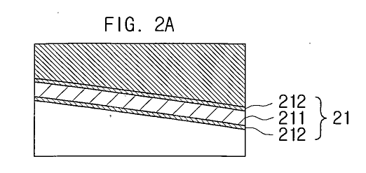

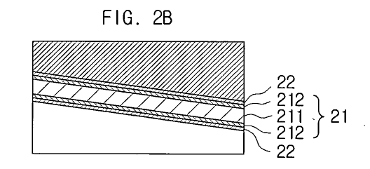

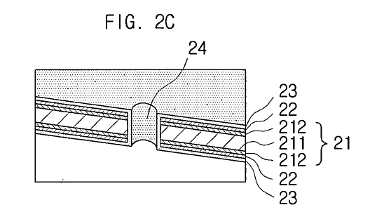

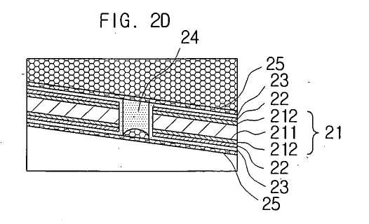

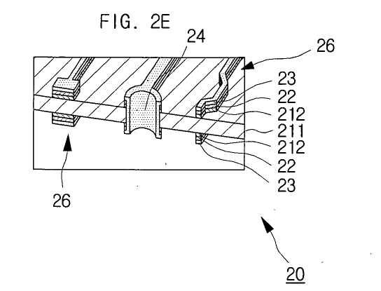

FIG. 1 is a flowchart for a method of manufacturing a heat-releasing printed circuit board according to a first disclosed embodiment of the invention, and FIGS. 2A to 2E are sectional views representing a flow diagram for manufacturing a heat-releasing printed circuit board according to the first disclosed embodiment of the invention. In FIGS. 2A to 2E are illustrated a heat-releasing PCB 20, a copper clad laminate 21, an insulation layer 211, copper layers 212, coating layers 22, plating layers 23, a through-hole 24, dry film 25, and circuit patterns 26.

Operation S11 may include preparing a copper clad laminate, in which copper layers may be stacked on an insulation layer, and the descriptions reference FIG. 2A. Prepreg may generally be used for the insulation layer 211. A copper clad laminate 21 may used, which is a typically used electrical material.

Operation S12 may include forming coating layers on the surfaces of the copper layers from paste having carbon nanotubes as a major constituent, where FIG. 2B illustrates an example of a corresponding process.

This operation may be to form the coating layers 22 on the surfaces of the copper layers using paste, which includes carbon nanotubes as a major constituent.

Forming the coating layers 22 by using carbon nanotubes in the form of a paste can provide excellent thermal conductivity. There can be many ways to make a paste using carbon nanotubes. The carbon nanotubes used for the paste can be of various types, including single-walled or multi-walled carbon nanotubes.

One method of fabricating carbon nanotube paste may be to adequately disperse the carbon nanotubes throughout a finished silver (Ag) paste product.

Another method of fabricating carbon nanotube paste may involve adequately distributing silver (Ag) particles, binders, and carbon nanotubes to fabricate a paste.

The processes for products of fabricating carbon nanotube paste are available in the related art and can be obtained in the market. Thus, the details in this matter will be omitted.

The coating layers 22 in operation S 12 can be obtained by spin coating the carbon nanotube paste described above. Spin coating can be advantageous in forming large-sized coating layers to a uniform thickness.

An operation of drying the coating layers 22 may be additionally performed. The drying can be performed at a temperature between approximately 150 to 300° C.

Operation S13 may be to manufacture a heat-releasing PCB by removing portions of the coating layers and portions of the copper layers to form circuit patterns.

Prior to operation S13, a through-hole 24 may be formed by perforating the coating layers 22 and the copper clad laminate 21. By forming a plating layers 23 inside, this through-hole 24 can serve as a via that connects the circuit patterns on the upper and lower sides. The through-hole 24 can be formed by mechanical drilling, while the plating layers 23 can be formed by forming seed layers by electroless plating and then forming electroplating over the seed layers. Performing a plating process on the through-hole 24 in this manner may result in an arrangement similar to that shown in FIG. 2C.

Afterwards, dry film 25 may be stacked on the surfaces of the plating layers 23, as illustrated in FIG. 2D, and then the dry film 25 may be removed by exposure and development processes in consideration of the portions where the circuit patterns 26 are to be formed.

Following the removal of the dry film 25, the exposed plating layers 23 may be treated with an etchant, which can remove the plating layers 23 made of metal (typically copper) and can infiltrate into the coating layers 22 to remove the copper layers 212 underneath. As a result, a heat-releasing PCB 20 having circuit patterns 26 formed can be completed, as illustrated in FIG. 2E.

As illustrated in FIG. 2E, the heat-releasing PCB 20 may be coated with the coating layers 22, which includes carbon nanotubes, as a part of the circuit patterns 26. Carbon nanotubes have a thermal conductivity of about 6000 W/mk, and can thus prove very effective as a heat-releasing material. Consequently, by forming a part of the circuit patterns 26 with the coating layers 22 that include carbon nanotubes as a major constituent, a superb heat-releasing effect can be obtained.

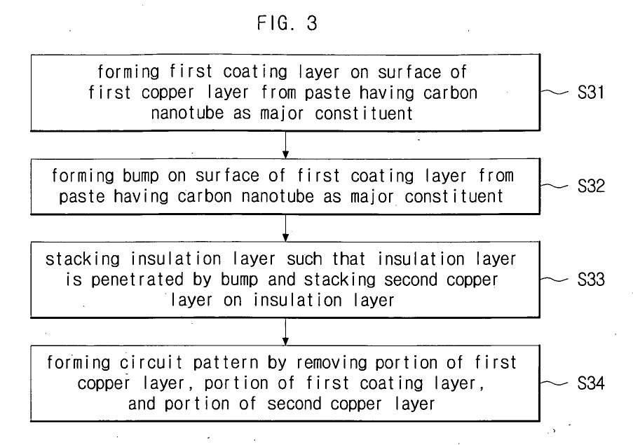

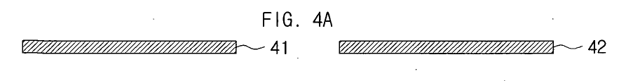

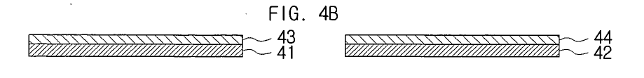

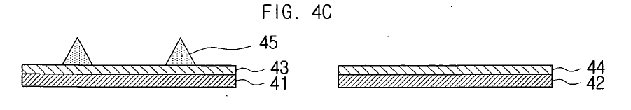

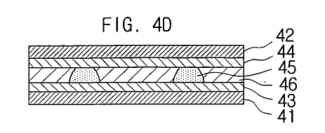

FIG. 3 is a flowchart for a method of manufacturing a heat-releasing printed circuit board according to a second disclosed embodiment of the invention, and FIGS. 4A to 4E are cross-sectional views representing a flow diagram for manufacturing a heat-releasing printed circuit board according to the second disclosed embodiment of the invention. In FIGS. 4A to 4E are illustrated a first copper layer 41, a second copper layer 42, a first coating layer 43, a second coating layer 44, bumps 45, an insulation layer 46, and circuit patterns 47.

Operation S31 may include forming a first coating layer, from a paste that includes carbon nanotubes as a major constituent, on a first copper layer, while FIG. 4B illustrates a corresponding process. The method of fabricating a paste that has carbon nanotubes as a main constituent is as already described with reference to the first disclosed embodiment, and thus will not be described again. The first coating layer 43 may additionally undergo a drying operation.

Meanwhile, a second coating layer 44 may be formed on a second copper layer 42 by a method similar to the method of stacking the first coating layer 43 on the first copper layer 41.

Operation S32 may include forming bumps, which include carbon nanotubes as a major constituent, on a surface of the first coating layer, while FIG. 4C illustrates a corresponding process. Here, the first coating layer 43 may be stacked on the surface of the first copper layer 41 by the process of operation S31. Onto this first coating layer 43, bumps 45 may be formed using a paste that includes carbon nanotubes as a major constituent. The bumps 45 can be put through a curing process to provide a sufficient degree of rigidity that allows the bumps to penetrate the insulation layer 46 in a subsequent process. It can be advantageous to form the bumps 45 to have a sharp end, for easier stacking of the insulation layer 46 in the subsequent process. In this particular embodiment, the bumps 45 are formed on just the first coating layer 43, and not on the second coating layer 44.

Operation S33 may include stacking an insulation layer, such that the bumps penetrate the insulation layer, and stacking a second copper layer on the insulation layer. FIG. 4D illustrates a corresponding process. The insulation layer 46 may be stacked from the direction where the bumps 45 are formed. In certain embodiments, the insulation layer 46 may desirably have a rigidity lower than that of the bumps 45. As such, a resin may be used that has a lower amount of glass fiber included. Also, the insulation layer 46 can be in a semi-cured state. Onto the insulation layer 46 may be stacked the second copper layer 42. In cases where a second coating layer 44 is stacked on the second copper layer 42, as in this particular embodiment, the second copper layer 42 can be stacked with the second coating layer 44 facing the bumps 45. Stacking the layers thus can result in the bumps 45, the first coating layer 43, and the second coating layer 44 all having the same carbon nanotube material and being directly connected.

While in this particular embodiment, a second coating layer 44 having carbon nanotubes as a major constituent is formed on the second copper layer 42, other embodiments may have the second copper layer 42 stacked on the insulation layer 46 without a second coating layer 44.

Operation S34 may include removing portions of the first copper layer, portions of the first coating layer, and portions of the second copper layer, to form circuit patterns. If a second coating layer 44 is stacked over the second copper layer 42, portions of the second coating layer 44 may have to be removed as well.

In the example illustrated in FIG. 4D, dry film (not shown) is stacked on the surfaces of the first copper layer 41 and the second copper layer 42, respectively. Portions of the dry film may be removed, in consideration of the positions where the circuit patterns 47 will be formed, by exposure and development processes. After removing the dry film, the exposed first and second copper layers 41, 42 may be removed using an etchant. Furthermore, portions of the first and second coating layers 43, 44, which are exposed when the portions of the first and second copper layers 41, 42 are removed, may also be removed, to complete the heat-releasing PCB 40, an example of which is shown in FIG. 4E. As the circuit patterns 47 of the heat-releasing PCB 40 include carbon nanotubes, which have a high thermal conductivity, an excellent heat-releasing effect can be provided.

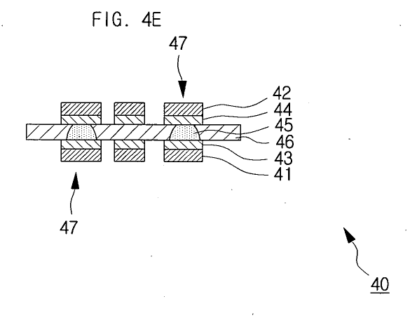

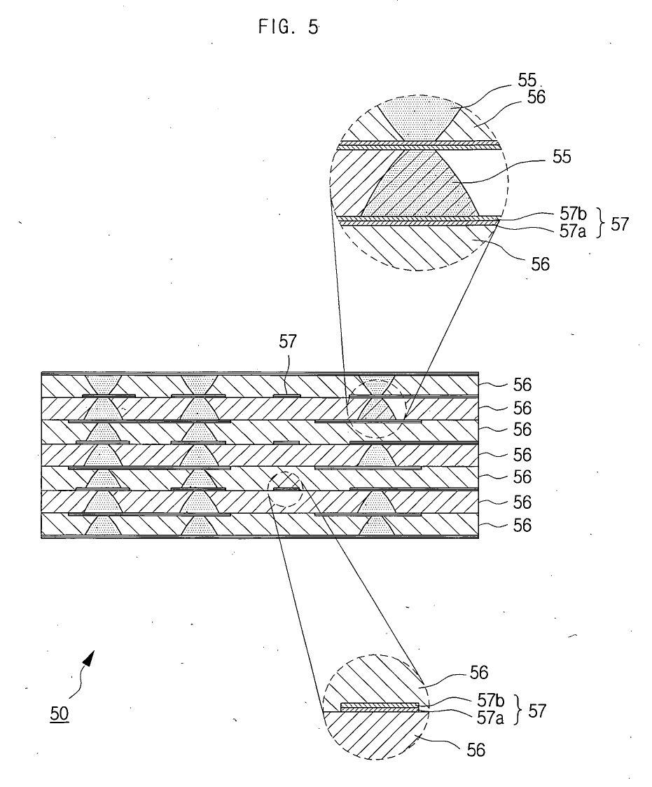

FIG. 5 is a cross-sectional view of a multi-layered heat-releasing printed circuit board according to a third disclosed embodiment of the invention. In FIG. 5 are illustrated a heat-releasing PCB 50, bumps 55, insulation layers 56, circuit patterns 57, copper patterns 57a, and coating layers 57b.

The heat-releasing PCB 50 of this particular embodiment is a multilayered board having circuit patterns 57 and insulation layers 56 stacked in alternation. Bumps 55 may be formed that penetrate insulation layers 56, in order to connect neighboring circuit patterns 57. The bumps 55 may include carbon nanotubes as a major constituent. Carbon nanotubes have a high thermal conductivity.

Also, the circuit patterns 57 may be formed to have coating layers 57b stacked on copper patterns 57a. The coating layers 57b may be formed by spin coating and curing carbon nanotube paste.

The method of fabricating such carbon nanotube paste is as already described with reference to the first disclosed embodiment.

As such, in the heat-releasing PCB 50 according to this embodiment, coating layers 57b that have carbon nanotubes as a main constituent can be included as a part of the circuit patterns 57, so that superb thermal conductivity may be provided.

While the spirit of the invention has been described in detail with reference to particular embodiments, the embodiments are for illustrative purposes only and do not limit the invention. It is to be appreciated that those skilled in the art can change or modify the embodiments without departing from the scope and spirit of the invention.

What is claimed is:

1. A method of manufacturing a heat-releasing printed circuit board, the method comprising:
preparing a copper clad laminate having at least one copper layer stacked on at least one insulation layer;
forming a coating layer on a surface of the copper layer, the coating layer made from a paste having carbon nanotubes as a major constituent; and
forming a circuit pattern by removing portions of the coating layer and portions of the copper layer.

2. The method of claim 1, further comprising, between forming the coating layer and forming the circuit pattern:
drying the coating layer.

3. The method of claim 2, further comprising, between drying the coating layer and forming the circuit pattern:
forming at least one through-hole by perforating the copper clad laminate and the coating layer; and
forming a plating layer inside the through-hole,
wherein forming the circuit pattern comprises removing portions of the plating layer.

4. A method of manufacturing a heat-releasing printed circuit board, the method comprising:
forming a first coating layer on a first copper layer, the first coating layer made from a paste having carbon nanotubes as a major constituent;
forming at least one bump on a surface of the first coating layer, the bump including carbon nanotubes as a major constituent;
stacking an insulation layer such that the bump penetrates the insulation layer, and stacking a second copper layer on the insulation layer; and
forming a circuit pattern by removing portions of the first copper layer, portions of the first coating layer, and portions of the second copper layer.

5. The method of claim 4, further comprising, between forming the first coating layer and forming the bump:
drying the first coating layer.

6. The method of claim 4, wherein a second coating layer is formed on the second copper layer, the second coating layer having carbon nanotubes as a major constituent,
stacking the second copper layer on the insulation layer is achieved by stacking the second copper layer such that the second coating layer faces the insulation layer, and
forming the circuit pattern comprises removing portions of the second coating layer.

7. A multi-layered heat-releasing printed circuit board having at least one insulation layer and at least one circuit pattern stacked alternately, the heat-releasing printed circuit board comprising a copper pattern and a coating layer stacked on a surface of the copper pattern, wherein the coating layer has carbon nanotubes as a major constituent.

8. The heat-releasing printed circuit board of claim 7, wherein at least one bump containing carbon nanotubes penetrate the insulation layer to connect adjacent circuit patterns.
